(19) United States
(12) Patent Application Publication
(10) Pub. No.: US 2026/0006717 A1
(43) Pub. Date: Jan. 1, 2026

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Chung-Chih YEN, Taichung City (TW); Chun-Chu LAI, Taichung City (TW)

(73) Assignee: SILICONWARE PRECISION INDUSTRIES CO., LTD., Taichung City (TW)

(21) Appl. No.: 18/967,241

(22) Filed: Dec. 3, 2024

(30) Foreign Application Priority Data
Jun. 28, 2024 (TW) 113124399

(51) Int. Cl. H05K 1/02; H01L 23/00; H01L 25/16; H01L 25/18; H05K 1/14; H05K 1/18; H05K 3/34; H05K 3/36

(52) U.S. Cl. CPC H05K 1/0298; H01L 25/16; H01L 25/18; H05K 1/145; H05K 1/181; H05K 3/3431; H05K 3/36; H01L 24/16; H01L 24/32; H01L 24/73; H01L 2224/16245; H01L 2224/32245; H01L 2224/73253; H01L 2924/37001; H05K 2201/0206; H05K 2201/0338; H05K 2201/0367; H05K 2203/1305

(57) ABSTRACT

An electronic package is provided. A plurality of conductive posts with multilayer composite materials and at least one electronic component are disposed on a carrier structure. An encapsulation layer covers the at least one electronic component and the plurality of conductive posts. A circuit structure is disposed on the encapsulation layer and is electrically connected to the plurality of conductive posts. Therefore, the multilayer composite materials for the conductive posts achieve CTE (coefficient of thermal expansion) matching, improve electrical conductivity, and prevent copper diffusion in high temperature or high frequency working environments. A manufacturing method of the electronic package is also provided.

### BACKGROUND

### 1. Technical Field

The present disclosure relates to a semiconductor packaging technology, and more particularly, to an electronic package and a manufacturing method thereof that can improve yield.

### 2. Description of Related Art

To ensure the continuation of miniaturization and multi-functionality of electronic products, semiconductor packages must evolve toward miniaturization to enable the interconnection of numerous pins and provide high functionality. For instance, in advanced packaging process, common packaging process types include 2.5D packaging process, fan-out wiring process, etc.

FIG. 1 is a schematic cross-sectional view of a conventional semiconductor package 1. In the semiconductor package 1, a first semiconductor chip 11 and a passive component 19 are disposed on a substrate structure 14 having a wiring layer 140 (the first semiconductor chip 11 is disposed on the substrate structure 14 via an adhesive 12), and then a first packaging layer 15 is formed and covers the first semiconductor chip 11 and the passive component 19. Next, a plurality of holes are formed on the first packaging layer 15 by laser, so that a plurality of conductive posts 13 are formed in the holes and are electrically connected to the wiring layer 140. Then, a circuit structure 10 is formed on the first packaging layer 15 and is electrically connected to the first semiconductor chip 11 and the conductive posts 13, a plurality of second semiconductor chips 16 are provided on the circuit structure 10 and are electrically connected to the circuit structure 10, and a second packaging layer 18 is formed and covers the second semiconductor chips 16. Thereafter, a plurality of solder balls 17 are formed on the substrate structure 14 and connected to a circuit board 1a.

However, in the conventional semiconductor package 1, the conductive posts 13 are formed by conventional electroplated copper post method, so voids are often easily formed due to the size variation of the lasered holes or the unevenness of the side walls of the lasered holes in the first packaging layer 15, resulting in poor yield.

In addition, the conductive posts 13 made of a single material are prone to have mismatch in coefficient of thermal expansion (CTE) and are also prone to have poor electrical properties (such as bridging between adjacent metal copper posts by the migrating copper particles) in high temperature or high frequency working environments, among other problems.

Therefore, how to overcome the above problems of the prior art has become an urgent problem to be solved.

### SUMMARY

In view of the various deficiencies of the prior art, the present disclosure provides an electronic package, which comprises: a carrier structure having a first side and a second side opposite to the first side; a plurality of conductive posts with multilayer composite materials disposed on the first side of the carrier structure and electrically connected to the carrier structure; at least one electronic component disposed on the first side of the carrier structure; an encapsulation layer formed on the first side of the carrier structure and covering the at least one electronic component and the plurality of conductive posts; and a circuit structure disposed on the encapsulation layer and electrically connected to the plurality of conductive posts.

The present disclosure further provides a method of manufacturing an electronic package, the method comprises: providing a carrier structure having a first side and a second side opposite to the first side; forming a plurality of conductive posts with multilayer composite materials on the first side of the carrier structure, and electrically connecting the plurality of conductive posts to the carrier structure; disposing at least one electronic component on the first side of the carrier structure; forming an encapsulation layer on the first side of the carrier structure, wherein the encapsulation layer covers the at least one electronic component and the plurality of conductive posts; and forming a circuit structure on the encapsulation layer, and electrically connecting the circuit structure to the plurality of conductive posts.

In the aforementioned electronic package and method, forming the plurality of conductive posts further comprises: forming a resist layer having a plurality of openings on the carrier structure; forming a first metal layer, a second metal layer and a third metal layer sequentially on the resist layer and in the plurality of openings; removing the first metal layer, the second metal layer and the third metal layer on the resist layer and retaining the first metal layer, the second metal layer and the third metal layer in the plurality of openings, allowing the first metal layer, the second metal layer and the third metal layer in the plurality of openings to serve as the plurality of conductive posts; and removing the resist layer. For instance, the first metal layer includes cobalt (Co) material or ruthenium (Ru) material, the second metal layer includes copper material, and the third metal layer includes copper material. Further, the present disclosure comprises forming a fill material at an innermost layer in the plurality of openings. For instance, the fill material is metal material or dielectric material.

In the aforementioned electronic package and method, the present disclosure further comprises forming a plurality of conductive bumps on the circuit structure.

In the aforementioned electronic package and method, the present disclosure further comprises disposing a functional component on the circuit structure.

In the aforementioned electronic package and method, the present disclosure further comprises forming a plurality of conductive components on the second side of the carrier structure.

As can be seen from the above, the electronic package and manufacturing method thereof of the present disclosure primarily employ multilayer composite materials for the conductive posts to achieve CTE matching, improve electrical conductivity, and prevent copper diffusion in high temperature or high frequency working environments. In comparison to the prior art, the electronic package of the present disclosure can improve the product yield of final product.

Moreover, the conductive posts are formed by electroplating multilayer composite materials within the openings of the resist layer, so that the dimensions of the openings in the resist layer are nearly identical, and the side walls in the openings are generally flat, as compared to the prior art. As a result, voids can be effectively prevented from forming in the conductive posts, so that the yield rate can be significantly improved.

In addition, the conductive posts can be formed using existing materials, existing processes and existing machinery, so there is no need to develop new processes and new materials, and there is no need to purchase new machinery. Consequently, the manufacturing method of the present disclosure does not result in a significant increase in cost expenditure.

### BRIEF DESCRIPTION OF THE DRAWINGS

FIG. 1 is a schematic cross-sectional view of a conventional semiconductor package.

FIG. 2A to FIG. 2E are schematic cross-sectional views illustrating a manufacturing method of an electronic package according to the present disclosure.

FIG. 3A to FIG. 3D are local enlarged schematic cross-sectional views illustrating a manufacturing method of conductive posts in FIG. 2A.

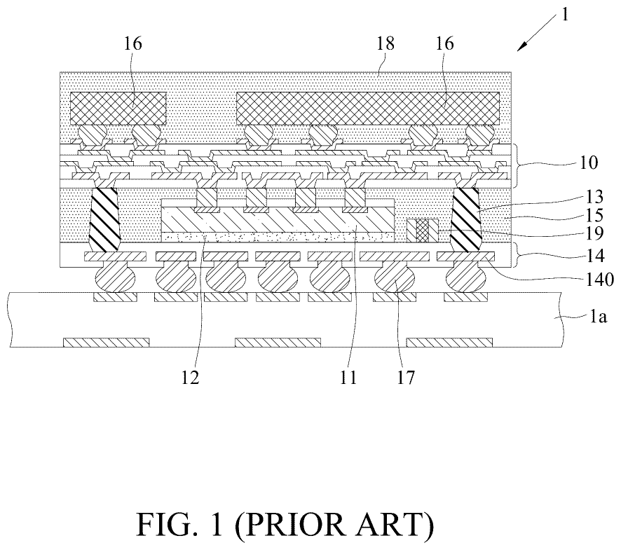

### DETAILED DESCRIPTION

The following describes the embodiments of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “upper,” “first,” “second,” “a,” “one,” and the like are merely used for clear explanation rather than limiting the practicable scope of the present disclosure, and thus, alterations or adjustments of the relative relationships thereof without essentially altering the technical contents should still be considered in the practicable scope of the present disclosure.

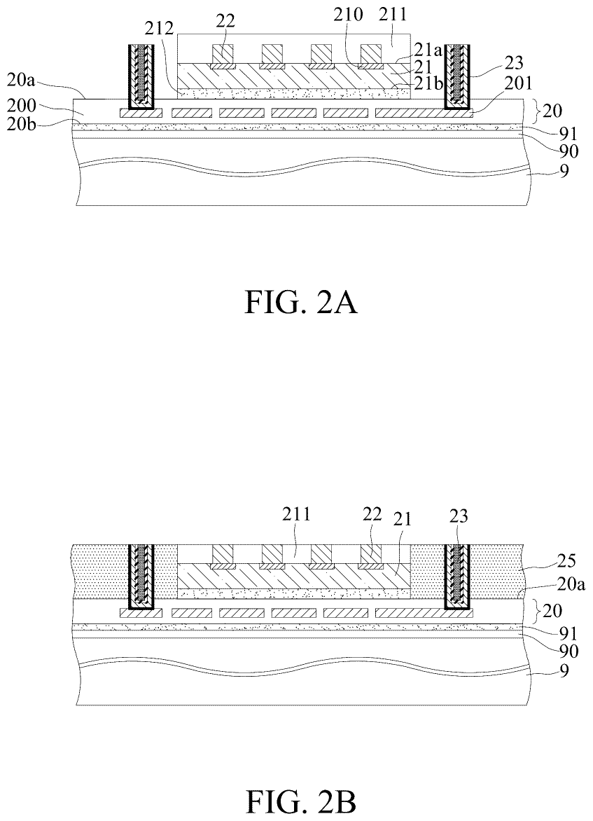

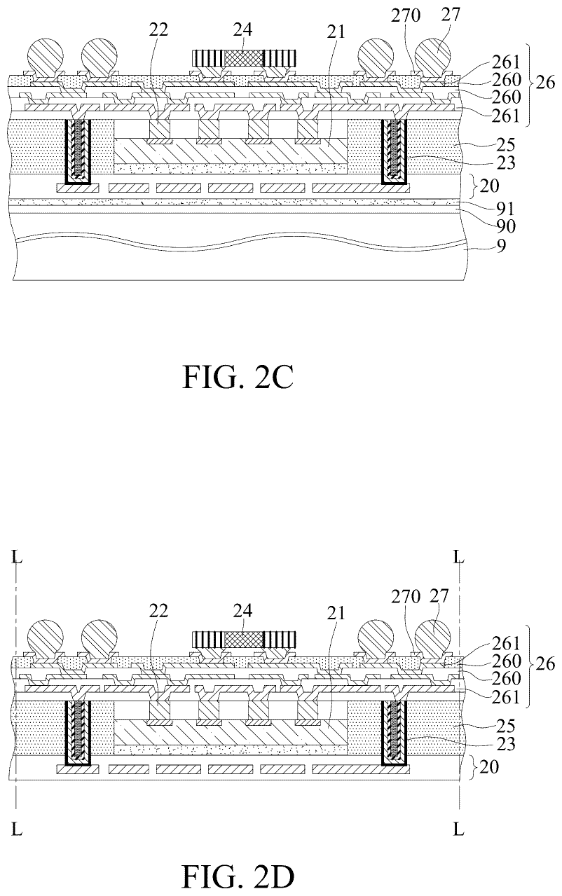

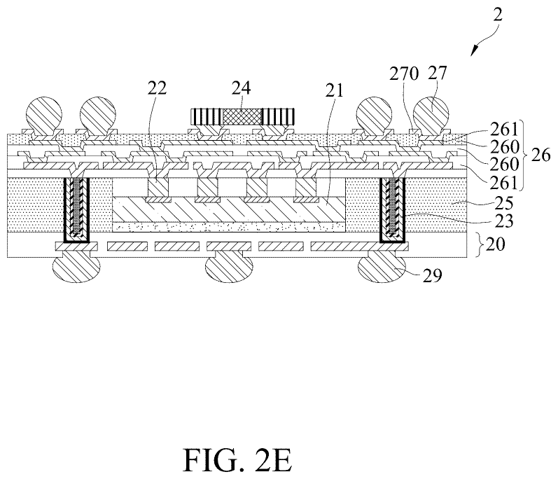

FIG. 2A to FIG. 2E are schematic cross-sectional views illustrating a manufacturing method of an electronic package 2 according to the present disclosure.

As shown in FIG. 2A, a carrier structure 20 is bonded on a support board 9. The carrier structure 20 has a first side 20a and a second side 20b opposite to the first side 20a, and the carrier structure 20 is bonded to the support board 9 via the second side 20b thereof. Further, a plurality of conductive posts 23 are formed on the first side 20a of the carrier structure 20 and are electrically connected to the carrier structure 20, and at least one electronic component 21 is disposed on the first side 20a of the carrier structure 20.

The carrier structure 20 includes at least one first insulating layer 200 and at least one first wiring layer 201 (e.g., a redistribution layer [RDL]) bonded to the first insulating layer 200. The carrier structure 20 is, for example, an RDL structure or a circuit board.

In one embodiment, the first wiring layer 201 is made of copper (Cu) material, and the first insulating layer 200 is made of polybenzoxazole (PBO), polyimide (PI), prepreg (PP), or other dielectric materials.

The support board 9 is, for example, a plate made of semiconductor material (e.g., silicon or glass), on which a release layer 90 and an adhesive layer 91 are sequentially formed in a manner of coating, so that the carrier structure 20 is disposed on the adhesive layer 91.

The conductive posts 23 are, for example, pillars, lines, or spheres, and the conductive posts 23 are erected on the first wiring layer 201 and are electrically connected to the first wiring layer 201.

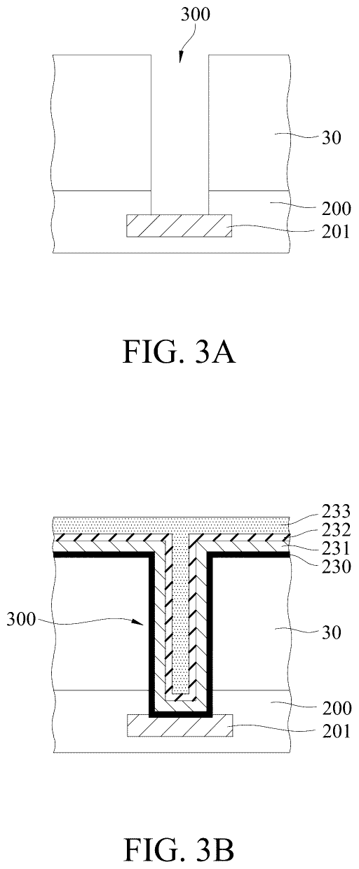

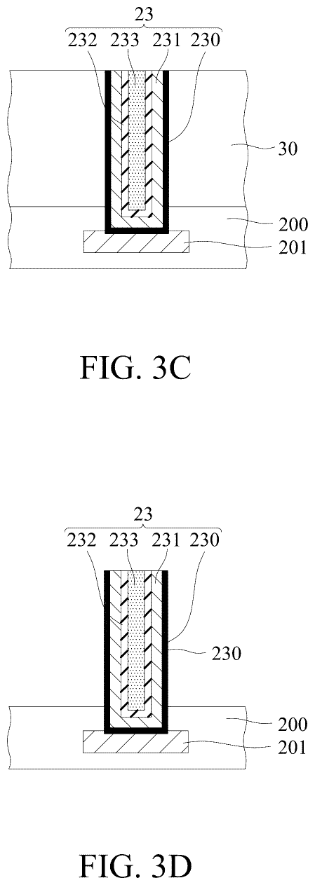

In one embodiment, the conductive posts 23 are in the form of multilayer composite materials, and a manufacturing method of the conductive posts 23 is detailed in FIG. 3A to FIG. 3D.

Please also refer to FIG. 3A together, a resist layer 30 is formed on the first insulating layer 200 and has a plurality of openings 300, so that parts of the surface of the first wiring layer 201 are exposed from the openings 300.

In one embodiment, the resist layer 30 is made of photoresist material, and is formed with patterned opening regions, i.e., the plurality of openings 300, via exposure and development processes.

Please also refer to FIG. 3B together, a first metal layer 230, a second metal layer 231, a third metal layer 232, and a fill material 233 are sequentially formed on the resist layer 30 and in the opening 300.

In one embodiment, the first metal layer 230 is made of cobalt (Co) material or ruthenium (Ru) material to prevent metal ions from migration, the second metal layer 231 and the third metal layer 232 are made of copper material, and the fill material 233 is a metal material or a dielectric material (e.g., SiO₂, SiN, PBO, or the like). For example, different metal materials (such as Cu, Co, Ru, etc.) are applied layer by layer to form a multilayer metal structure by using physical deposition, chemical deposition, physical vapor deposition (PVD), chemical vapor deposition (CVD), atomic layer deposition (ALD), or methods.

Please also refer to FIG. 3C together, materials on the resist layer 30 (i.e., the first metal layer 230, the second metal layer 231, and the third metal layer 232) are removed, and materials in the opening 300 (i.e., the first metal layer 230, the second metal layer 231, and the third metal layer 232) are retained so as to serve as the conductive post 23.

Please also refer to FIG. 3D together, the resist layer 30 is removed.

It should be appreciated that the composition material and the number of layers of the conductive post 23 can be designed according to requirements and are not limited to as such.

The electronic component 21 is an active component, a passive component, or a combination of the active component and the passive component. The active component is, for example, a semiconductor chip, and the passive component is, for example, a resistor, a capacitor, or an inductor.

In one embodiment, the electronic component 21 is a semiconductor chip and has an active surface 21a and an inactive surface 21b opposite to the active surface 21a. The inactive surface 21b of the electronic component 21 is attached to the first side 20a of the carrier structure 20 via a die attach layer 212, and a plurality of electrode pads 210 are formed on the active surface 21a. A plurality of conductors 22 are formed on the plurality of electrode pads 210, and a protective film 211 is formed and covers the plurality of electrode pads 210 and the plurality of conductors 22. For instance, the protective film 211 is made of insulating material such as PBO. The conductors 22 are, for example, conductive circuits/lines, spherical conductors such as solder balls, post-shaped metal conductors such as copper posts, solder bumps, etc., or stud-shaped conductors made by a wire bonding machine, but not limited to these.

As shown in FIG. 2B, an encapsulation layer 25 is formed on the first side 20a of the carrier structure 20 and covers the electronic component 21 and the plurality of conductive posts 23. Then, by a leveling process, an upper surface of the encapsulation layer 25 is coplanar with an upper surface of the protective film 211, end surfaces of the conductive posts 23 and end surfaces of the conductors 22, so that the upper surface of the protective film 211, the end surfaces of the conductive posts 23 and the end surfaces of the conductors 22 are exposed from the encapsulation layer 25.

In one embodiment, the encapsulation layer 25 is made of insulating material, such as polyimide (PI), dry film, epoxy (e.g., epoxy resin), or molding compound (e.g., epoxy molding compound), and the encapsulation layer 25 is formed on the first side 20a of the carrier structure 20 in a manner of lamination or molding.

Furthermore, in the leveling process, parts of the conductive posts 23, the protective film 211, the conductors 22 and the encapsulation layer 25 are removed by grinding, so that the upper surface of the encapsulation layer 25 is flush with the upper surface of the protective film 211, the end surfaces of the conductive posts 23 and the end surfaces of the conductors 22.

As shown in FIG. 2C, a circuit structure 26 is formed on the encapsulation layer 25 and is electrically connected to the plurality of conductive posts 23.

In one embodiment, the circuit structure 26 includes a plurality of second insulating layers 260 and a plurality of second wiring layers 261 such as RDLs formed on the second insulating layers 260, and the second wiring layers 261 are electrically connected to the plurality of conductive posts 23 and the plurality of conductors 22 on the electronic component 21. An outermost second insulating layer 260 may serve as a solder-resist layer, and an outermost second wiring layer 261 is exposed from the solder-resist layer to serve as electrical contact pads. Alternatively, the circuit structure 26 may only include a single second insulating layer 260 and a single second wiring layer 261.

Further, the second wiring layer 261 is made of copper material, and the second insulating layer 260 is made of dielectric material such as PBO, PI, or PP.

In addition, a plurality of conductive bumps 27 may be formed on the outermost second wiring layer 261. For instance, an under bump metallurgy (UBM) layer 270 may be formed on the outermost second wiring layer 261 so as to facilitate bonding of the plurality of conductive bumps 27, and the plurality of conductive bumps 27 are made of such as solder material and are of controlled collapse chip connection (C4) specification.

Moreover, a functional component 24 may be disposed on the outermost second wiring layer 261. For instance, the functional component 24 is an active component, a passive component, or a combination of the active component and the passive component. The active component is, for example, a semiconductor chip, and the passive component is, for example, a resistor, a capacitor, or an inductor, but the functional component 24 is not limited to as such.

As shown in FIG. 2D, the support board 9 and the release layer 90 and the adhesive layer 91 thereon are removed to expose the second side 20b of the carrier structure 20.

As shown in FIG. 2E, a plurality of conductive components 29 such as solder balls are formed on the second side 20b of the carrier structure 20. A singulation process is performed along a cutting path L of FIG. 2D so as to obtain the electronic package 2.

Accordingly, the manufacturing method of the present disclosure primarily employs multilayer composite materials for the conductive posts 23 to achieve CTE matching, improve electrical conductivity, and prevent copper diffusion in high temperature or high frequency working environments. In comparison to the prior art, the electronic package 2 of the present disclosure can enhance the product yield of final product.

Moreover, the conductive posts 23 are formed by electroplating multilayer composite materials within the openings 300 of the resist layer 30. The dimensions of the openings in the resist layer 30 are nearly identical, and the side walls in the openings 300 are generally flat, as compared to the prior art. As a result, voids can be effectively prevented from forming in the conductive posts 23, so that the yield rate can be significantly improved.

In addition, the conductive posts 23 can be formed using existing materials, existing processes and existing machinery, so there is no need to develop new processes and new materials, and there is no need to purchase new machinery. Consequently, the manufacturing method of the present disclosure does not result in a significant increase in expenditure.

The present disclosure provides an electronic package 2, which includes a carrier structure 20, a plurality of conductive posts 23 with multilayer composite materials, at least one electronic component 21, an encapsulation layer 25, and a circuit structure 26.

The carrier structure 20 has a first side 20a and a second side 20b opposite to the first side 20a.

The plurality of conductive posts 23 are disposed on the first side 20a of the carrier structure 20 and are electrically connected to the carrier structure 20.

The electronic component 21 is disposed on the first side 20a of the carrier structure 20.

The encapsulation layer 25 is formed on the first side 20a of the carrier structure 20 and covers the electronic component 21 and the plurality of conductive posts 23.

The circuit structure 26 is disposed on the encapsulation layer 25 and is electrically connected to the plurality of conductive posts 23.

In an embodiment, each of the plurality of conductive posts 23 includes a first metal layer 230, a second metal layer 231 and a third metal layer 232 in order from an outer layer to an inner layer. For example, the first metal layer 230 includes cobalt material or ruthenium material, and the second metal layer 231 and/or the third metal layer 232 include copper material. Further, each of the plurality of conductive posts 23 includes a fill material 233, such as metal material or dielectric material, at an innermost layer.

In an embodiment, the electronic package 2 further comprises a plurality of conductive bumps 27 formed on the circuit structure 26.

In an embodiment, the electronic package 2 further comprises at least one functional component 24 disposed on the circuit structure 26.

In an embodiment, the electronic package 2 further comprises a plurality of conductive components 29 formed on the second side 20b of the carrier structure 20.

In conclusion, the electronic package and manufacturing method thereof of the present disclosure primarily employ multilayer composite materials for the conductive posts to achieve CTE matching, improve electrical conductivity, and prevent copper diffusion in high temperature or high frequency working environments. Therefore, the electronic package of the present disclosure can improve the product yield of final product.

Moreover, the conductive posts are formed by electroplating multilayer composite materials within the openings of the resist layer. The dimensions of the openings in the resist layer are nearly identical, and the side walls in the openings are generally flat, as compared to the prior art. As a result, voids can be effectively prevented from forming in the conductive posts, so that the yield rate can be significantly improved.

In addition, the conductive posts can be formed using existing materials, existing processes and existing machinery, so there is no need to develop new processes and new materials, and there is no need to purchase new machinery. Consequently, the manufacturing method of the present disclosure does not result in a significant increase in expenditure, such that the manufacturing cost can be effectively reduced.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
a carrier structure having a first side and a second side opposite to the first side;
a plurality of conductive posts with multilayer composite materials disposed on the first side of the carrier structure and electrically connected to the carrier structure;
at least one electronic component disposed on the first side of the carrier structure;
an encapsulation layer formed on the first side of the carrier structure and covering the at least one electronic component and the plurality of conductive posts; and
a circuit structure disposed on the encapsulation layer and electrically connected to the plurality of conductive posts.

2. The electronic package of claim 1, wherein each of the plurality of conductive posts includes a first metal layer, a second metal layer and a third metal layer in order from an outer layer to an inner layer.

3. The electronic package of claim 2, wherein the first metal layer includes cobalt material or ruthenium material.

4. The electronic package of claim 2, wherein the second metal layer includes copper material.

5. The electronic package of claim 2, wherein the third metal layer includes copper material.

6. The electronic package of claim 2, wherein each of the plurality of conductive posts further includes a fill material at an innermost layer.

7. The electronic package of claim 6, wherein the fill material is metal material or dielectric material.

8. The electronic package of claim 1, further comprising a plurality of conductive bumps formed on the circuit structure.

9. The electronic package of claim 1, further comprising a functional component disposed on the circuit structure.

10. The electronic package of claim 1, further comprising a plurality of conductive components formed on the second side of the carrier structure.

11. A method of manufacturing an electronic package, the method comprising:
providing a carrier structure having a first side and a second side opposite to the first side;
forming a plurality of conductive posts with multilayer composite materials on the first side of the carrier structure, and electrically connecting the plurality of conductive posts to the carrier structure;
disposing at least one electronic component on the first side of the carrier structure;
forming an encapsulation layer on the first side of the carrier structure, wherein the encapsulation layer covers the at least one electronic component and the plurality of conductive posts; and
forming a circuit structure on the encapsulation layer, and electrically connecting the circuit structure to the plurality of conductive posts.

12. The method of claim 11, wherein forming the plurality of conductive posts further comprises:
forming a resist layer having a plurality of openings on the carrier structure;
forming a first metal layer, a second metal layer and a third metal layer sequentially on the resist layer and in the plurality of openings;
removing the first metal layer, the second metal layer and the third metal layer on the resist layer and retaining the first metal layer, the second metal layer and the third metal layer in the plurality of openings, allowing the first metal layer, the second metal layer and the third metal layer in the plurality of openings to serve as the plurality of conductive posts; and
removing the resist layer.

13. The method of claim 12, wherein the first metal layer includes cobalt material or ruthenium material.

14. The method of claim 12, wherein the second metal layer includes copper material.

15. The method of claim 12, wherein the third metal layer includes copper material.

16. The method of claim 12, further comprising forming a fill material at an innermost layer in the plurality of openings.

17. The method of claim 16, wherein the fill material is metal material or dielectric material.

18. The method of claim 11, further comprising forming a plurality of conductive bumps on the circuit structure.

19. The method of claim 11, further comprising disposing a functional component on the circuit structure.

20. The method of claim 11, further comprising forming a plurality of conductive components on the second side of the carrier structure.
